(19) United States
(12) Patent Application Publication
(10) Pub. No.: US 2014/0001561 A1
(43) Pub. Date: Jan. 2, 2014

(54) CMOS DEVICES HAVING STRAIN SOURCE/DRAIN REGIONS AND LOW CONTACT RESISTANCE

(71) Applicants: Kangguo Cheng, Schenectady, NY (US); Ali Khakifirooz, Mountain View, CA (US); Alexander Reznicek, Troy, NY (US); Thomas N. Adam, Slingerlands, NY (US)

(72) Inventors: Kangguo Cheng, Schenectady, NY (US); Ali Khakifirooz, Mountain View, CA (US); Alexander Reznicek, Troy, NY (US); Thomas N. Adam, Slingerlands, NY (US)

(73) Assignee: INTERNATIONAL BUSINESS MACHINES CORPORATION, ARMONK, NY (US)

(21) Appl. No.: 13/534,522

(22) Filed: Jun. 27, 2012

(51) Int. Cl. H01L 27/092; H01L 21/8238

(52) U.S. Cl. 257/369; 438/233; 257/E27.062; 257/E21.634

(57) ABSTRACT

A CMOS device structure and method of manufacturing the same are provided. The CMOS device structure includes a substrate having a first region and a second region. The CMOS device structure further includes a first gate formed in the first region overlying a first channel region in the substrate. The CMOS device structure further includes a first pair of source/drain regions formed in the first region on either side of the first channel region. Each region of the pair of source/drain regions has a substantially V-shaped concave top surface.

### BACKGROUND

### Field of the Invention

The present invention relates to microelectronic devices, and more particularly, to devices having strain source/drain regions and low contact resistance.

Transistors are multi-electrode semiconductor devices in which the current flowing between two specified electrodes is controlled or modulated by the voltage applied at a third (control) electrode. Transistors fall into two major classes: field-effect transistors (FETs), and bipolar junction transistors (BJTs).

FETs include a source, a drain, and a gate. A voltage applied to the gate results in a current flow between the source and the drain of the FET through a channel that is formed beneath the gate. A commonly used FET is a complimentary metal oxide semiconductor transistor, or CMOS transistor.

CMOS device performance is dependent upon numerous factors, one being the total device resistance. The total device resistance is, in turn, a function of parameters such as contact resistance, wiring resistance, channel resistance, etc. Decreasing the total device resistance can improve device performance (i.e. improve device speed). As CMOS devices scale further downward, the contact resistance becomes a higher portion of the total resistance due to the fact that channel resistance decreases while metal contact resistance increases with the scaling trend. Metal contact resistance increases due to the reduction of source/drain area.

Both theoretical and empirical studies have demonstrated that carrier mobility with a transistor is greatly increased when a strain is applied to the transistor's conduction channel. In p-type FETs (“PFET”), the application of a compressive longitudinal strain to the conduction channel is known to increase the drive currents of the PFET. However, if that same strain is applied to the conduction channel of an n-type FET (“NFET”), its performance decreases.

Accordingly, it would be desirable to provide a process for applying a desired strain in the channel region of a PFET without creating the same strain in the channel region of the NFET, while simultaneously achieving a low metal contact resistance, in order to enhance CMOS devices' performance.

### SUMMARY

In an aspect of the invention, a semiconductor device structure includes a substrate having a first region and a second region. The semiconductor device structure further includes a first gate formed in the first region overlying a first channel region in the substrate. The semiconductor device structure further includes a first pair of source/drain regions formed in the first region on either side of the first channel region. Each region of the pair of source/drain regions has a substantially V-shaped concave top surface.

In another aspect of the invention, a method for fabricating a semiconductor device structure includes providing a substrate having a first region and a second region. The method further includes forming a first gate in the first region. The first gate overlies a first channel region in the substrate. The method further includes forming a first pair of source/drain regions in the first region on either side of the first channel region. The method further includes forming a substantially V-shaped groove on a top surface of each of the first pair of source/drain regions.

A more complete understanding of the present invention, as well as further features and advantages of the present invention, will be obtained by reference to the following detailed description and drawings. It is to be understood that both the foregoing general description and the following detailed description are exemplary and explanatory only, and should not be considered restrictive of the scope of the invention, as described and claimed. Further, features or variations may be provided in addition to those set forth herein. For example, embodiments of the invention may be directed to various combinations and sub-combinations of the features described in the detailed description.

BRIEF DESCRIPTION OF THE SEVERAL VIEWS OF THE DRAWINGS

The present invention is described in the detailed description which follows in reference to the noted plurality of drawings by way of non-limiting examples of exemplary embodiments of the present invention.

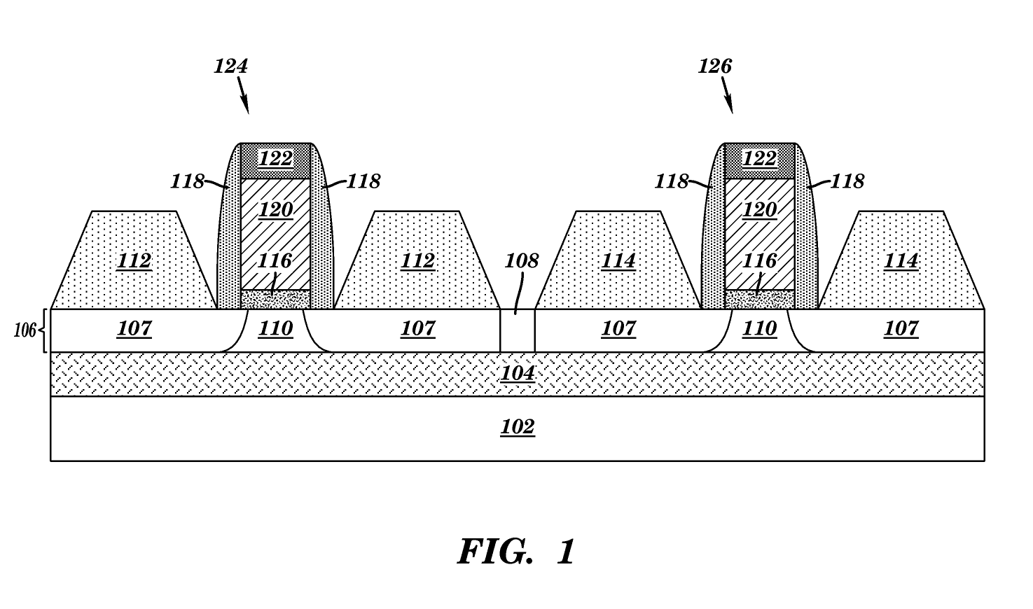

FIGS. 1 through 6 schematically illustrate method steps for fabrication of a CMOS semiconductor device structure in accordance with an embodiment of the present invention.

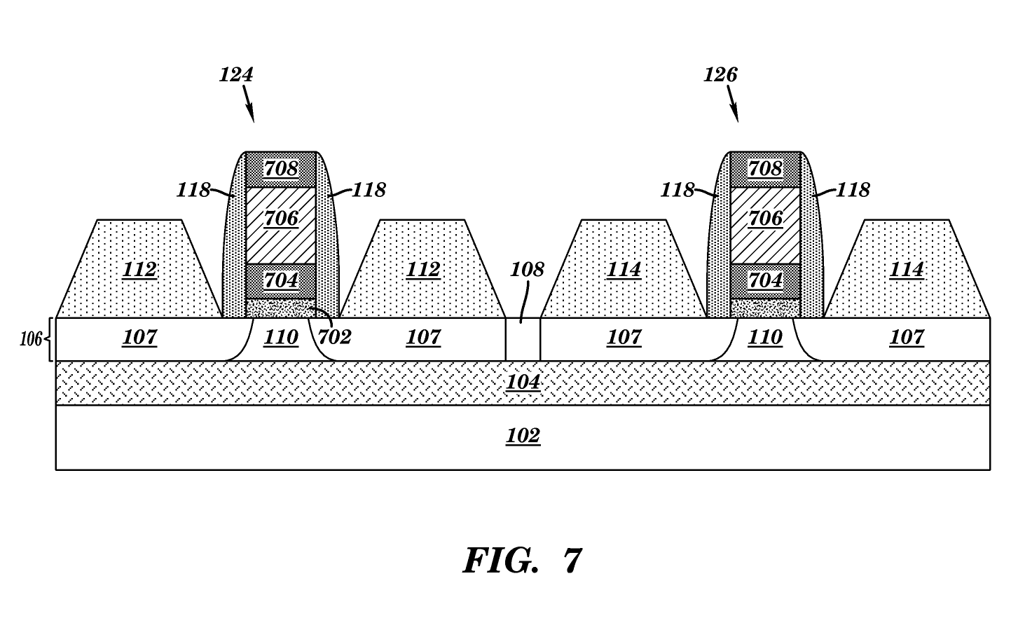

FIGS. 7 through 12 schematically illustrate method steps for fabrication of a CMOS semiconductor device structure in accordance with another embodiment of the present invention.

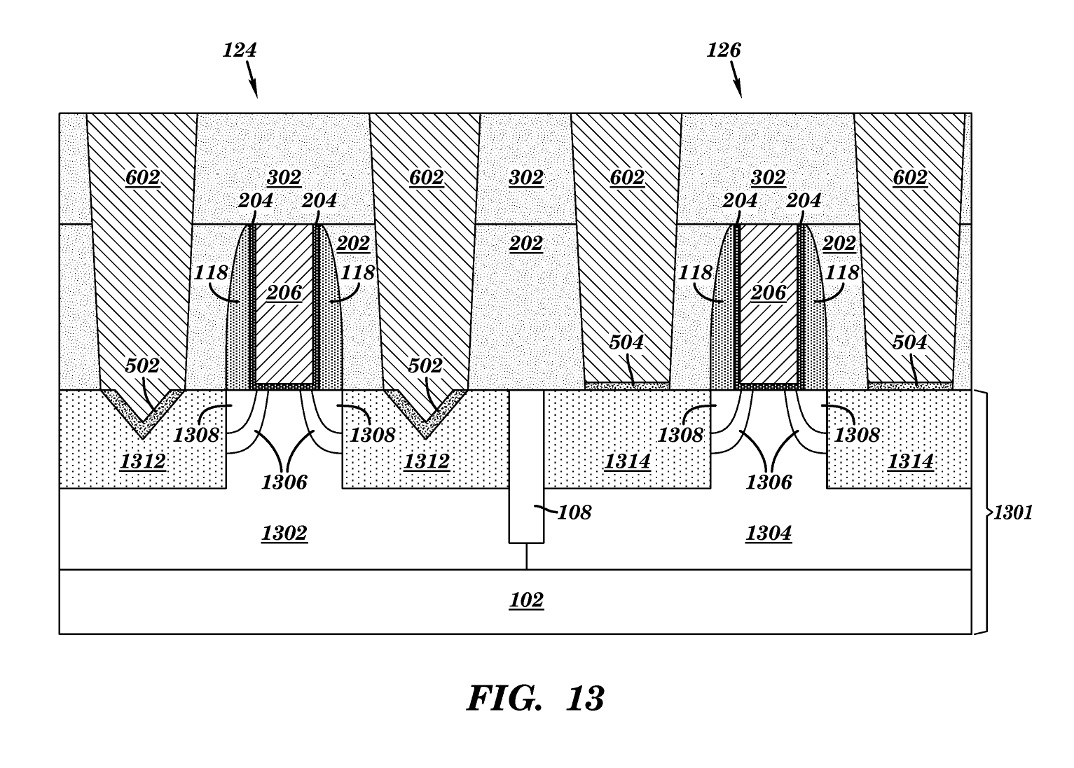

FIG. 13 schematically illustrates a CMOS semiconductor device structure in accordance with yet another embodiment of the present invention.

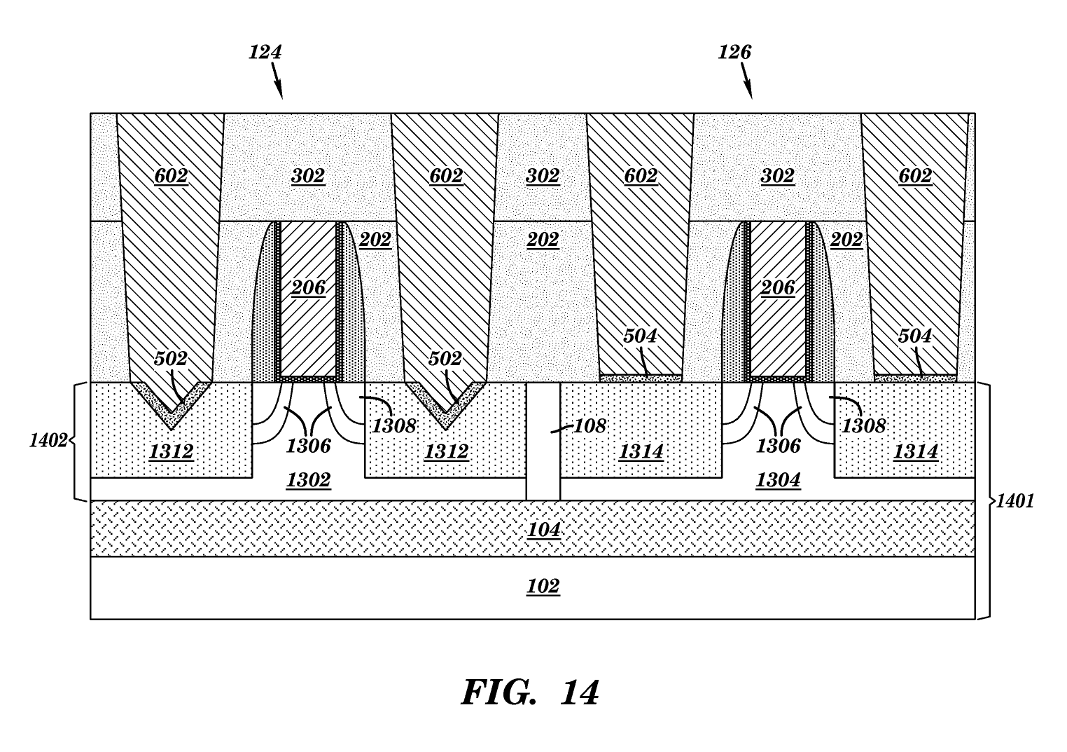

FIG. 14 schematically illustrates a CMOS semiconductor device structure in accordance with still another embodiment of the present invention.

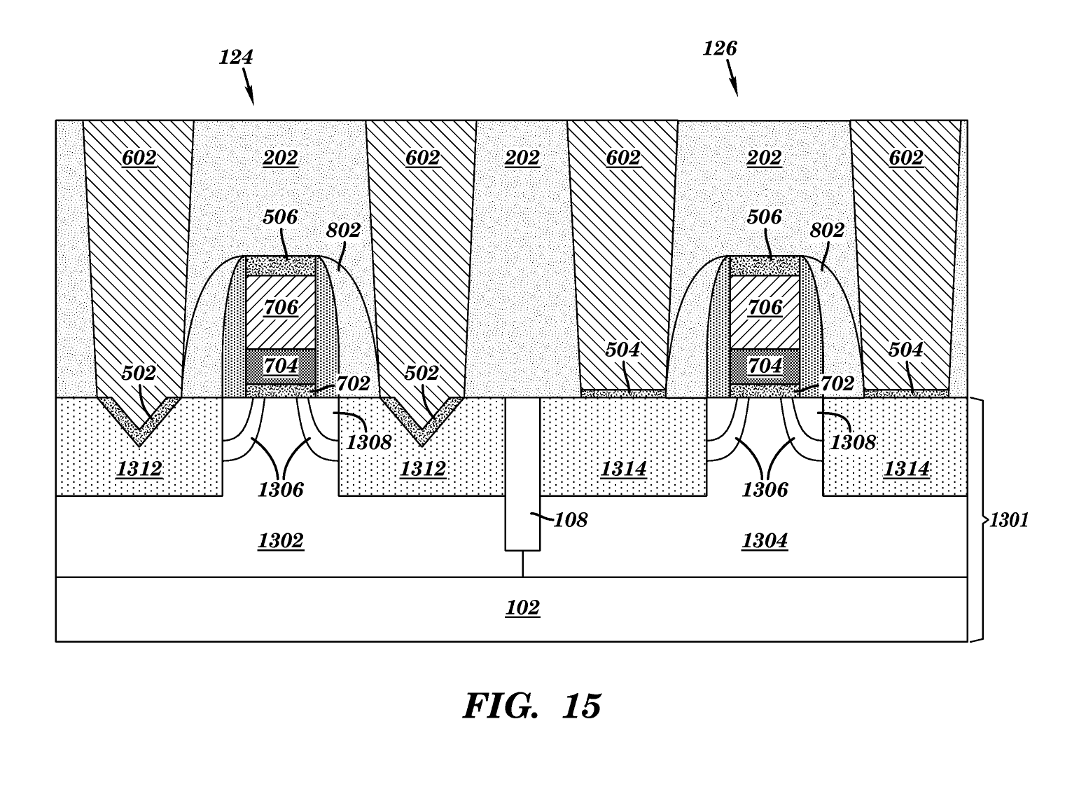

FIG. 15 schematically illustrates a CMOS semiconductor device structure in accordance with yet another embodiment of the present invention.

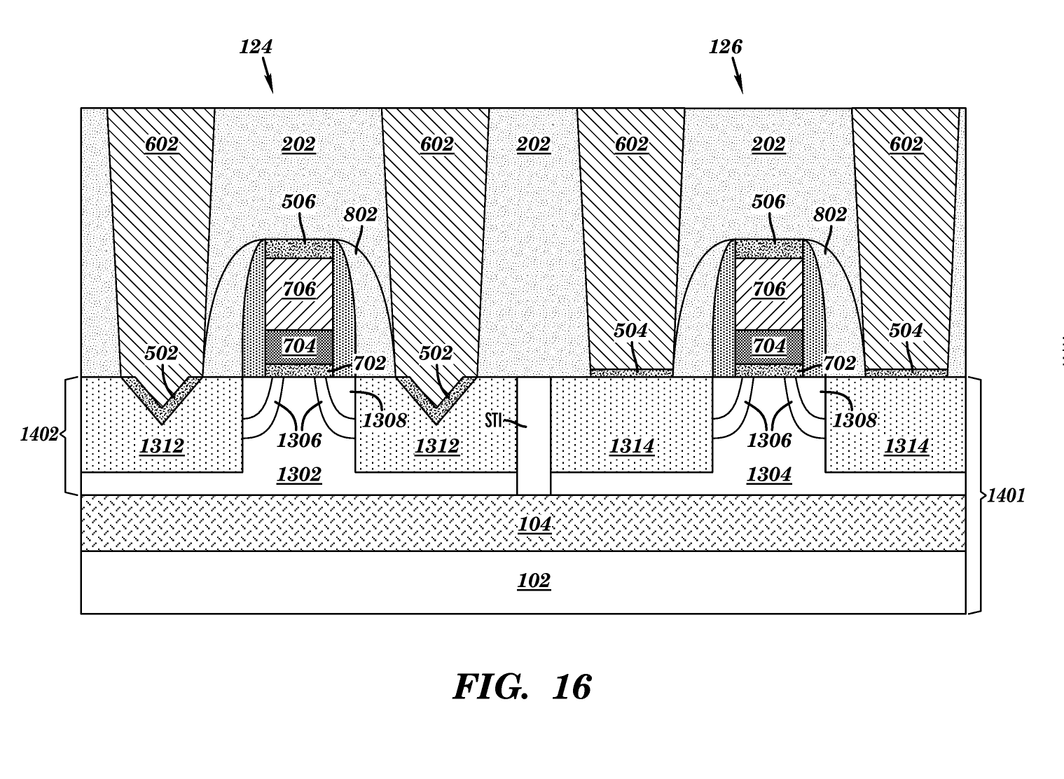

FIG. 16 schematically illustrates a CMOS semiconductor device structure in accordance with still another embodiment of the present invention.

### DETAILED DESCRIPTION

An embodiment of the present invention relates to a structure and method of forming CMOS devices. More specifically, an embodiment of the present invention comprises a semiconductor device structure which includes a substrate having a first region and a second region. The semiconductor device structure further includes a first gate formed in the first region overlying a first channel region in the substrate. The semiconductor device structure further includes a first pair of source/drain regions formed in the first region on either side of the first channel region. Each region of the pair of source/drain regions has a substantially V-shaped concave top surface. Advantageously, the structures of disclosed embodiments of the present invention are an improvement over prior art because they allow to simultaneously achieve low silicide resistance and increase the stress to device channel. Some exemplary embodiments of the present invention provide a structure and a method of manufacturing a CMOS device having raised source/drain regions, while other exemplary embodiments of the present invention provide a structure and a method of manufacturing the CMOS device having embedded source/drain regions. The methods and devices disclosed herein may be implemented in either a gate first process or a gate last process. As discussed below, the embodiments of the present invention are applicable to a variety of substrates including bulk silicon, Extremely Thin Semiconductor-on-Insulator (“ETSOI”), Partially Depleted (“PD”) SOI, and the like. ETSOI devices are attractive due to their ability to control short-channel effects entirely by ultra-thin SOI without channel doping. Thus, ETSOI is the preferred substrate and the various embodiments are illustrated using an ETSOI substrate, however, the embodiments may also be implemented using bulk or SOI substrates.

FIGS. 1 through 6 schematically illustrate method steps for fabrication of a CMOS semiconductor device structure on an ETSOI substrate using a gate last process in accordance with an embodiment of the present invention.

Referring initially to FIG. 1, there is shown a cross-sectional view of two conventionally formed ETSOI FET devices, such as NFET 124 and PFET 126 of CMOS circuitry. NFET 124 and PFET 126 may be manufactured in two adjacent regions on the same semiconductor substrate. For example, as shown in FIG. 1. NFET may be fabricated in a first region (NFET region) 124 over the ETSOI substrate and PFET may be fabricated in a second region (PFET region) 126. Regions 124 and 126 may be adjacent to each other.

Semiconductor substrate 102 may be any type of wafers of suitable semiconductor material. Preferably, the initial substrate is a single crystal silicon wafer. Semiconductor substrate 102 may be of a p-type lightly doped semiconductor substrate, as is well known in the art. As is shown a bulk substrate 102 has a buried insulator layer 104 (in this instance a buried oxide layer or BOX) formed thereon. BOX layer 104 may have a thickness from approximately 5 nm to approximately 200 nm. A thin semiconductor layer 106 (hereafter referred to as ETSOI layer) is in turn formed over the BOX layer 104. The ETSOI layer 106 may comprise any semiconducting material including, but not limited to Si, strained Si, Si:C, SiGe, SiGeC, Si alloys, Ge, Ge alloys, GaAs, InAs, and InP, or any combination thereof. The ETSOI layer 106 may be thinned to a desired thickness by planarization, grinding, wet etch, dry etch, oxidation followed by oxide etch, or any combination thereof. One method of thinning the ETSOI layer 106 is to oxidize the Si by a thermal dry or wet oxidation process, and then wet etch the oxide layer using a hydrofluoric acid mixture. This process can be repeated to achieve the desired thickness. In one embodiment, the ETSOI layer 106 has a thickness ranging from about 1.0 nm to about 20.0 nm. In another embodiment, the ETSOI layer 106 has a thickness ranging from about 1.0 nm to about 5.0 nm. In a further embodiment, the ETSOI layer 106 has a thickness ranging from about 3.0 nm to about 8.0 nm.

Structures associated with FET devices include NFET 124 and PFET 126 separated by isolation region 108. The isolation region 108 may utilize isolation technology, such as local oxidation of silicon (LOCOS) or shallow trench isolation (STI), to define and electrically isolate individual transistors 124 and 126. In at least one embodiment, the isolation region 108 includes a STI. In some embodiments, the isolation region 108 may comprise silicon oxide, silicon nitride, silicon oxynitride, fluoride-doped silicate glass (FSG), a low-K dielectric material, other suitable materials, and/or combinations thereof. The isolation region 108, and in the present embodiment, the STI, may be formed by any suitable process. As one example, the formation of the STI may include patterning the ETSOI layer 106 by a conventional photolithography process, etching a trench in the ETSOI layer 106 (for example, by using a dry etching, wet etching, and/or plasma etching process), and filling the trench (for example, by using a chemical vapor deposition process) with a dielectric material. In some embodiments, the filled trench may have a multi-layer structure such as a thermal oxide liner layer filled with silicon nitride or silicon oxide.

Still referring to FIG. 1, the method continues with formation of a dummy gate (or sacrificial gate) structure(s) by sequentially depositing and patterning a dummy oxide layer 116 and a dummy electrode layer 120 on the ETSOI layer 106. The dummy gate structures may be formed using any suitable process, including the processes described herein. In one exemplary embodiment of the present invention, the dummy oxide layer 116 and dummy gate electrode layer 120 are sequentially deposited on the ETSOI layer 106. In at least one embodiment, the dummy oxide layer 116 is preferably formed of silicon oxide grown by a thermal oxidation or deposition process, having a thickness from about 1 nm to about 10 nm. For example, the dummy oxide layer 116 can be grown by the rapid thermal oxidation (RTO) process or in an annealing process comprising oxygen. The dummy oxide layer 116 separates the dummy gate electrode layer 120 from the channel region 110. In some embodiments, the dummy gate electrode layer 120 may comprise a single layer or multilayer structure. In at least one embodiment, the dummy gate electrode layer 120 may comprise polysilicon. Further, the dummy gate electrode 120 may be doped polysilicon. The dummy gate electrode layer 120 may comprise any suitable thickness. In at least one embodiment, the dummy gate electrode layer 120 comprises a thickness in the range of about 10 nm to about 150 nm. In some embodiments, the dummy electrode layer 120 is preferably formed using a chemical vapor. Then, a thin cap layer 122 may be formed on top of the dummy gate structures. The thin cap layer 122 is formed of, in an embodiment, nitride. In at least one embodiment, the cap layer 122 comprises a thickness in the range of about 5 nm to about 100 nm.

A set of spacers 118 can be formed in direct contact with the sidewalls of the dummy gate structure. The spacers 118 are typically narrow having a width ranging from about 3 nm to about 20 nm. The spacers 118 can be formed using deposition and etch processing steps. The spacers 118 may be composed of a dielectric, such as, for example, but not limited to, nitride, oxide, oxynitride, or a combination thereof. The thickness of the spacers 118 determines the proximity of the subsequently formed raised source/drain (RSD) regions to the channel 110 of the device.

Next, pairs of RSD regions 112 and 114 may be formed in the first and the second regions, respectively. The pairs of RSD regions 112 and 114 may be formed in various ways. One preferred method will now be discussed. In this exemplary embodiment, an epitaxial or amorphous layer of, for example silicon or carbon doped silicon (Si:C) 112 is selectively formed over ETSOI layer 106 in the NFET region 124 adjacent dummy gate structure, as shown in FIG. 1. It should be noted that carbon doped silicon may be utilized to increase the amount of stress in the channel region 110. In one embodiment, the carbon concentration of the epitaxial carbon doped silicon layer 112 is less than 4%. Similarly, an epitaxial layer of, for example, silicon germanium (SiGe) 114 is selectively formed over the ETSOI layer 106 in the PFET region 126. Epitaxy is selective with respect to oxide and nitride, so there is no deposition on cap layer 122, the spacers 118 and the isolation region 108.

The pair of RSD regions 112 in the NFET region 124 and the pair of RSD regions 114 in the PFET region 126 may be doped with an appropriate dopant. For the RSD regions 112 in the NFET region 124, an n-type dopant, such as phosphorous or arsenic may be used. For the RSD regions 114 in the PFET region 126, a p-type dopant, such as boron may be used. Preferably, RSD regions 112 and 114 are doped in situ by appropriate means of deposition and masking. Alternatively, RSD regions 112 and 114 can be doped by plasma doping or ion implantation. Extensions (discussed below in conjunction with FIG. 13) can be formed in substrate level source/drain regions 107 by performing a thermal anneal to drive dopants in the RSD regions 112 and 114 towards device channel 110. Alternatively, extensions can be formed by other suitable doping technique such as implantation before or after formation of the RSD regions 112 and 114.

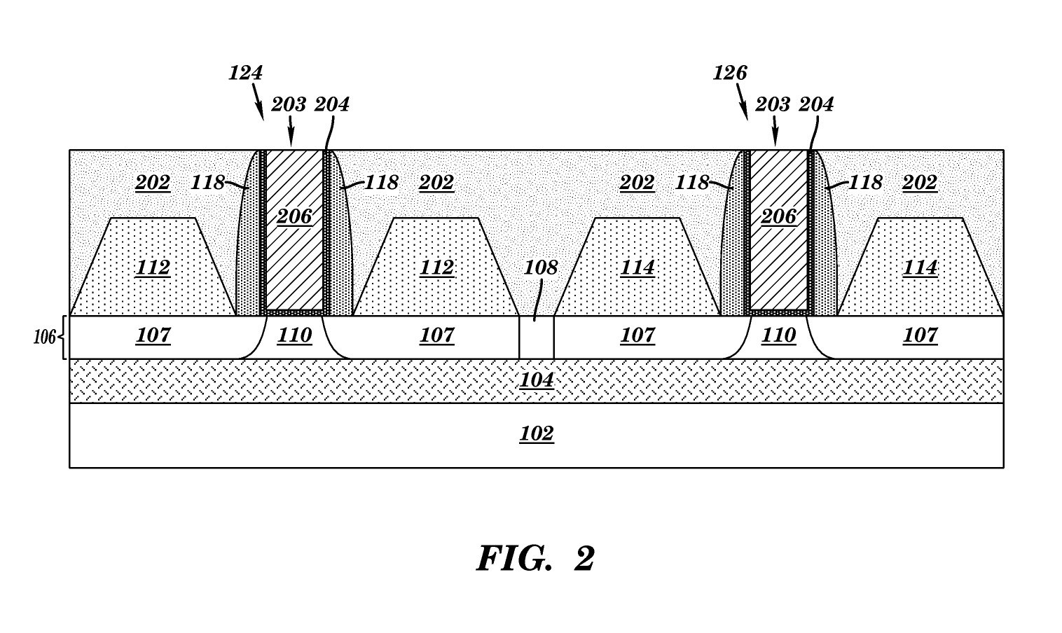

Next, as shown in FIG. 2, an interlayer dielectric (ILD) 202 is deposited and planarized. As a non-limiting example, the ILD 202 may comprise an oxide. Thereafter, and as illustrated in FIG. 2 the dummy gates are removed from both the NFET region 124 and PFET region 126 thereby forming a plurality of trenches 203. The dummy gates may be removed by a selective etching process. The selective etching process may employ either a wet etching method or a dry etching method. In one embodiment, a wet etching process includes exposure to a hydroxide containing solution (e.g. ammonium hydroxide), de-ionized water, and/or other suitable etchant solutions. In alternate embodiment of the invention, a dry etch process may be used to selectively remove the dummy gates. The dry etch process may comprise exposing the dummy gate to a plasma derived from materials that include, but are not limited to, hydrogen chloride (HCl), chlorine (Cl), sulfur hexafluoride (SF₆), hydrogen bromide (HBr), and/or hydrogen iodide (HI). Such a selective dry etch process may take place in a parallel plate reactor or in an electron cyclotron resonance etcher. Dummy oxide layer 116, shown in FIG. 1, may be removed as well. In one embodiment, a hydrogen fluoride (HF) etchant or a conventional wet etchant may be used to remove the dummy oxide layer 116.

Next, a high-k dielectric layer 204 may be conformally deposited within the gate trench 203 left by removing the dummy gate and the dummy oxide layer. As shown in FIG. 2, the conformal deposition of the high-k gate dielectric layer 204 may cover the sidewalls and bottom of the gate trench 203. The high-k dielectric layer 204 may be formed using materials that include, but are not limited to, hafnium oxide, hafnium silicon oxide, hafnium silicon oxynitride, lanthanum oxide, zirconium oxide, zirconium silicon oxide, tantalum oxide, titanium oxide, barium strontium titanium oxide, BST, barium titanium oxide, strontium titanium oxide, yttrium oxide, aluminum oxide, lead scandium tantalum oxide, lead zinc niobate, and PZT. Although a few examples of materials that may be used to form high-k gate dielectric layer are described here, that layer may be formed using other materials that serve to reduce gate leakage. In some embodiments, the high-k dielectric layer 204 may be formed using a conventional deposition process, including but not limited to atomic layer deposition (ALD), CVD, low pressure CVD, PECVD, or physical vapor deposition (PVD). In some embodiments, the thickness of the resulting high-k gate dielectric layer may range from about 1 nm to about 10 nm.

In the present embodiment, a metal layer 206 may be formed next to fill in the trenches 203. The metal layer 206 deposited may be any metal material suitable for forming a metal gate or portion thereof. The metal layer 206 may include one or more layers including TiN, TaN, TaC, TaSiN, W, TaCN, Al, Ti, WN, TiAl, TiAlN, combinations thereof, and/or other suitable materials. For example, for an NFET device in the NFET region 124 an N-type work function metal, such as TiAl, TiAlN, or TaCN, may be used. On the other hand, for a PFET device in the PFET region 126 a P-type work function metal, such as TiN, WN, or W, may be used. The metal layer 206 may be formed by PVD (sputtering), or other suitable processes.

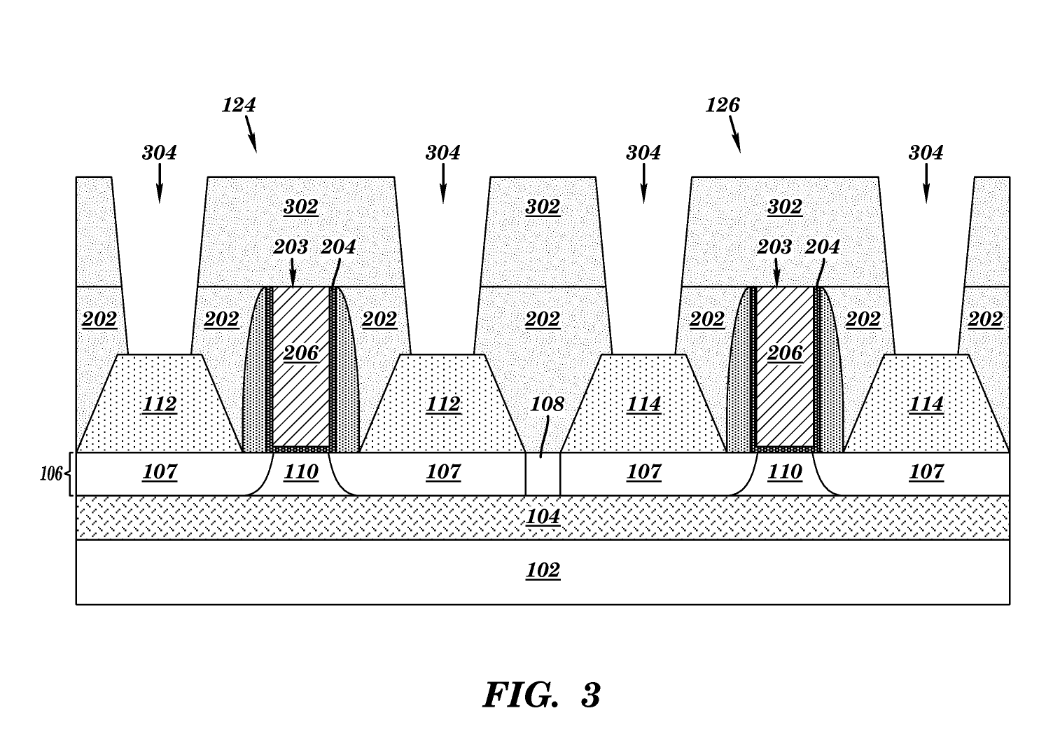

Referring now to FIG. 3, an oxide layer 302 may then be deposited over the ILD layer 202 and the high-k 204/metal 206 gate transistors. The oxide layer 302 may be silicon dioxide (SiO₂), or more generally SiOₓ. Other suitable dielectric materials may also be used for forming oxide layer 302. The oxide layer 302 may be deposited using processes such as CVD, ALD, or PECVD. FIG. 3 illustrates the oxide layer 302 that is deposited over the ILD layer 202 and the high-k/metal gate transistors in the NFET 124 and PFET 126 regions.

Contact trenches 304 may then be etched through the oxide layer 302 and ILD layer 202 that extend down to the pairs of RSD regions 112 and 114. FIG. 3 illustrates such contact trenches 304 that have been etched through the oxide layer 302 and the ILD layer 202 and that stop on the first pair of RSD regions 112 in the NFET region 124 and stop on the second pair of RSD regions 114 in the PFET region 126. It is within the contact trenches 304 that electrical contacts to the high-k/metal gate transistors will be formed. In various embodiments of the present invention, contact trenches 304 may be formed using conventional lithography and etching (reactive-ion etching (RIE), plasma etching, ion beam etching and other like dry etch process). Although not shown in the drawings, the lithography step may employ a conventional photoresist, which may be removed after the contact trenches 304 have been formed in the NFET 124 and PFET 136 regions, respectively. In various embodiments, each contact trench 304 extends across the length of the RSD regions 112 and 114 upon which it is formed in a direction that is substantially parallel to the metal gate 206, as shown in FIG. 3.

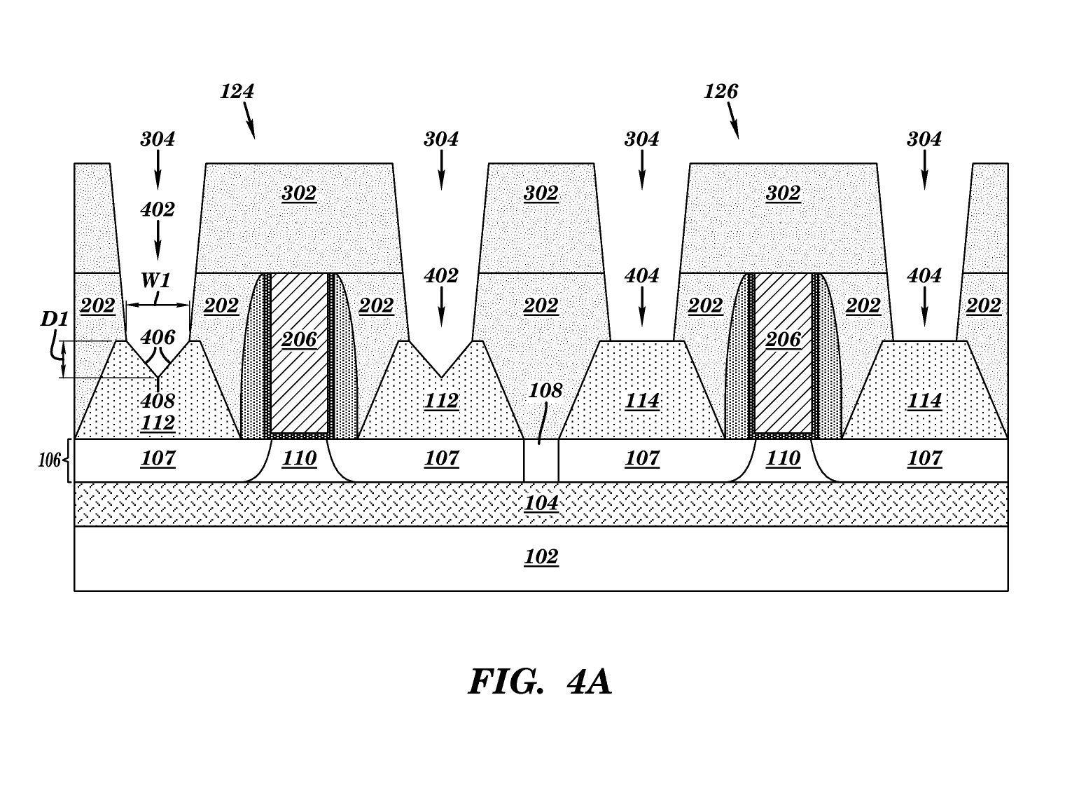

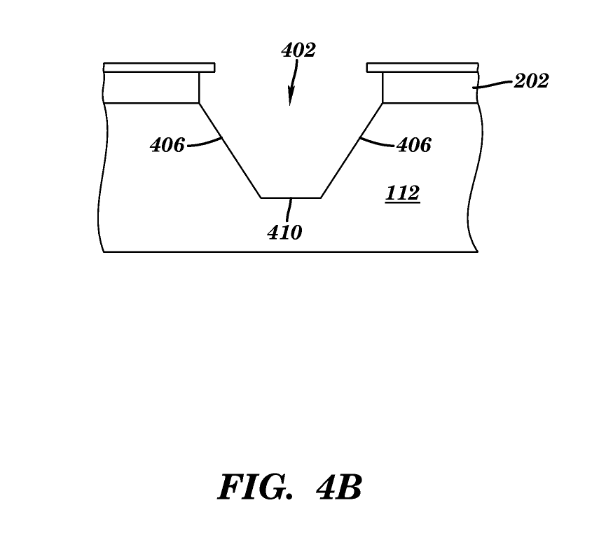

Next, a groove 402 on a top surface of each of the first pair of source/drain regions 112 may be formed as shown in FIG. 4A. The substantially V-shaped groove 402 on the top surface of the first pair of RSD regions 112 may be formed using an anisotropic wet etchant. In one embodiment of the present invention, a tetramethylammonium hydroxide (TMAH) or ammonium hydroxide (NH₄OH) solution with an appropriate pH value may be used to selectively etch the exposed first pair (n-type) of RSD regions 112 without affecting the exposed second pair (p-type) of RSD regions 114. Advantageously, without using any mask, this etchant is highly selective to boron-doped silicon germanium or silicon, and thus leaves in place substantially horizontal top surface of each of the second pair of RSD regions 114 while the formation of the groove 402 on the top surface of each of the first pair of RSD regions 112 occurs. The V-shape is formed because the etch rate in the <111> crystallographic plane is slower than in any of the other planes. Therefore, the etch stops substantially at <111> plane since the etch rate is very slow as compared to <100> and <110> crystallographic planes. The depth “D1” (measured from the top surface of RSD region 112) of V-shaped groove 402 is primarily a function of width “W1” of contact trench 304 and secondarily of etch time. Of note is that the wet etch of an embodiment of the present invention is substantially self-limiting. More specifically, as the wet etch of an embodiment progresses along sidewalls 406 of groove 402, the two sidewalls 406 meet essentially at the edge 408 to form an etch with an overall “V” shape. Given the directionally selective nature of the wet etch of an embodiment, once the sidewalls 406 have met, the rate at which the wet etch proceeds further within the RSD region 112 substantially decreases. Accordingly, the <111> crystallographic plane acts as an etch stop.

FIG. 4B illustrates an alternative shape for substantially V-shaped groove 402 of FIG. 4A. In FIG. 4B, the sidewalls 406 of V-shaped groove 402 do not meet, but instead a flat bottom 410 is formed. Flat bottom 410 may be formed simply by the first pair of RSD regions 412 for less time then that required for forming a “V” shape.

As stated earlier, the substantially V shaped groove can be made without masking the other FET. However, if desired, the other FET may be masked while creating the substantially V-shaped groove.

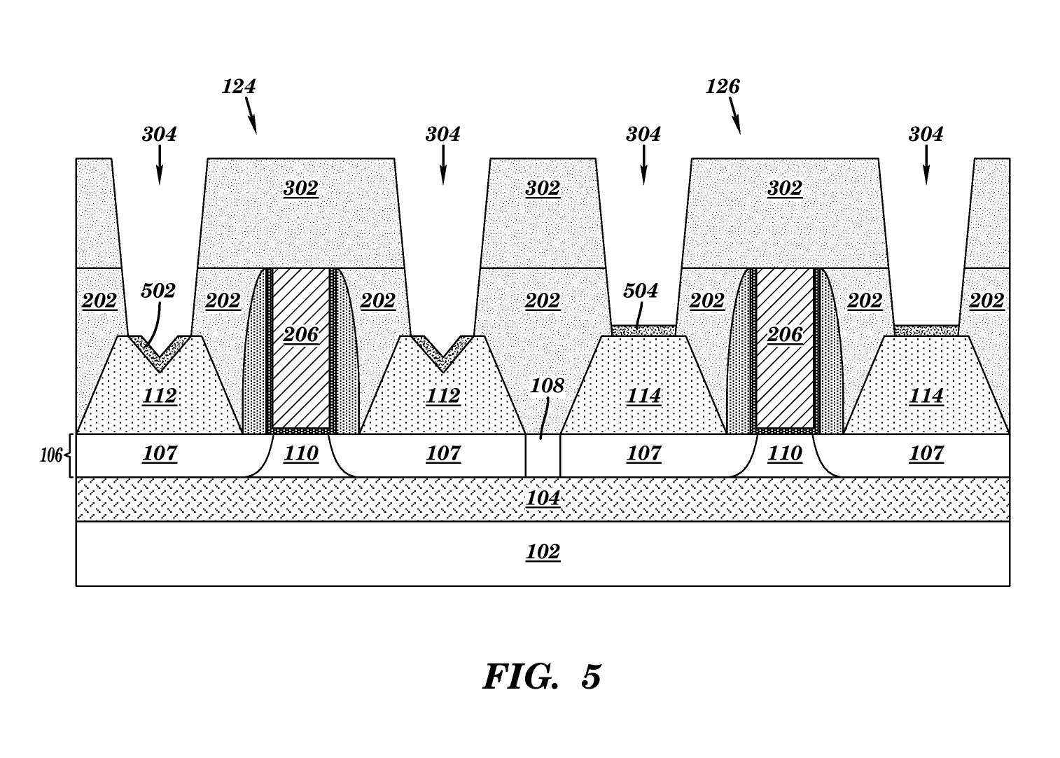

Once the substantially V-shaped groove 402 on the top surface of each of the first pair of source/drain regions 112 is obtained, the process may continue with the conventional process flow for CMOSFET device formation. As shown in FIG. 5, silicide layers 502 and 504 may be formed above each pair of the RSD regions 112 and 114, respectively using traditional processing techniques. For example, a layer of refractory metal (not shown in FIG. 5) is formed above the RSD regions 112, 114. The refractory metal layer may comprise a variety of materials that may be subsequently converted to a metal silicide 502 and 504. For example, the refractory metal layer may comprise cobalt, titanium, tantalum, tungsten, molybdenum, zirconium, platinum, nickel, and the like. The refractory metal layer may be formed by a variety of known techniques for forming such layers, such as, for example, a physical vapor deposition (PVD), sputtering, plasma enhanced chemical vapor deposition (PECVD), sputtering, LPCVD, and the like. The refractory metal layer may then converted to metal silicide layers 502 and 504, as shown in FIG. 5, above each of the RSD regions 112, 114 using known silicidation processing techniques. The thickness of the metal silicide layers 502 and 504 may be varied as a matter of design choice. However, using current generation technology, the metal silicide layers 502 and 504 may have a thickness ranging from about 5 nm to about 50 nm. It should be noted that in the NFET region 124 a layer of refractory metal is substantially conformally deposited over non-planar top surface of RSD regions 112, while in the PFET region 126 the layer of refractory metal is substantially conformally deposited over a planar top surface of RSD regions 114. Thus, the resulting silicide layers 502 and 504 follow the topography of the underlying layers. In other words, in the NFET region 124, the silicide layer 502 has a substantially V-shaped profile, while in the PFET region 126, the silicide layer 504 has a substantially horizontal profile, as shown in FIG. 5. The V-shape silicide layer 502 in the NFET region 124 increases the silicide to RSD 112 contact area and thus reduces contact resistance.

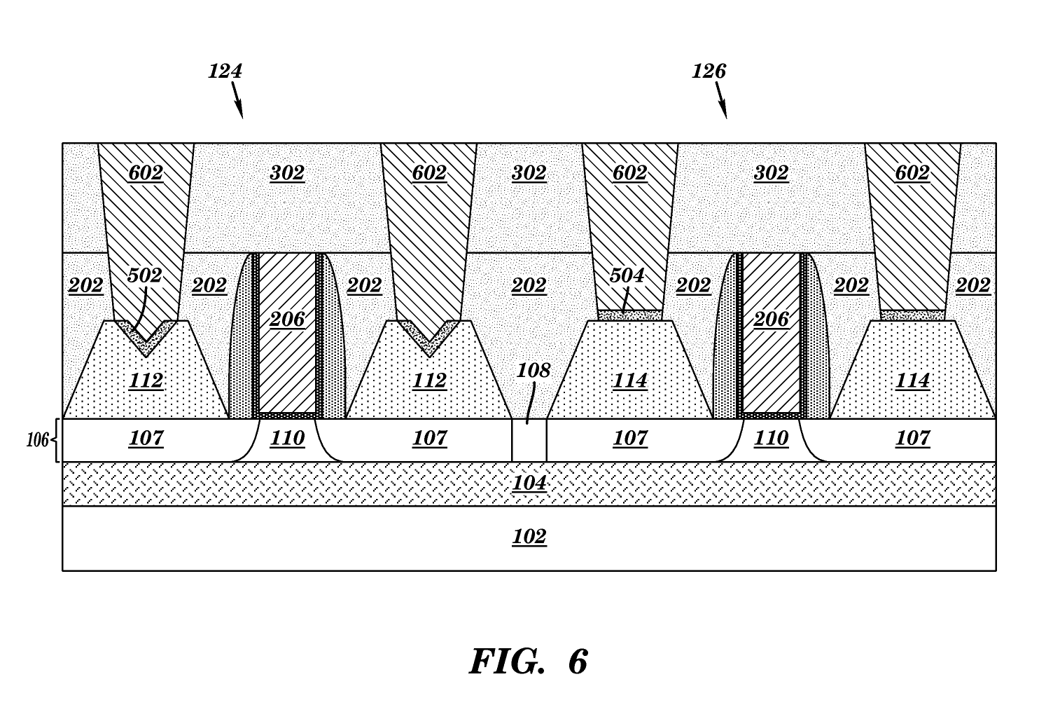

Turning to FIG. 6, a contact metal 602 is shown formed in (filled) contact trenches 304. In the present embodiment, in the NFET region 124 contact metal 602 may be deposited over V-shaped silicide layer 502, while in the PFET region 126 contact metal 602 may be deposited over substantially horizontal silicide layer 504. Contact metal 602 may be deposited using any conventional deposition techniques described herein and/or known in the art. Contact metal 602 may include, for example, but is not limited to, tungsten, aluminum, and/or copper. Contact metal 602 may provide a contact between NFET device 124, PFET device 126 and external circuitry, other semiconductor devices, etc. (not shown).

Thus, an embodiment of the present invention described above relates to a structure and a method of forming CMOS devices on an ETSOI substrate. The CMOS device comprises a NFET device formed in the first region 124 and PFET device formed in the second region 126. The first and second regions, 124 and 126, respectively are adjacent regions of the ETSOI substrate. The CMOS device structure further includes a first gate 206 formed in the first region 124 overlying a first channel region 110 in the substrate. According to an embodiment of the present invention, the structure of NFET device 124 includes a pair of source/drain regions 112 having a substantially V-shaped concave top surface. Furthermore, the structure of NFET device 124 includes a silicide layer 502 overlying the top surface of the RSD 112. Advantageously, the silicide layer 502 has a substantially V-shaped profile. In accordance with one advantageous aspect of this embodiment, the effective contact area between the silicide layer 502 and RSD regions 112 is increased in the NFET region 124 by changing the profile of the silicide layer 502. Furthermore, the increase in the contact area reduces contact resistance and improves device performance. In addition, the contact metal 602 overlying the V-shaped silicide layer 502 induces a tensile strain in the NFET region 124, which increases electron mobility in the channel 110. It should be noted that a compressive strain in the PFET region 126 is not affected because silicide layer 504 in the PFET region 126 is substantially horizontal. Furthermore, an embodiment of the present invention described above advantageously achieves improved manufacturability by minimizing variation in recess depth D1 (shown in FIG. 4A) due to self-limiting nature of the recess formation step. In accordance with yet another advantageous aspect of the present embodiment, the selective etch of the top surface of RSD 112 in the NFET region 124 is accomplished without adding a mask step in the PFET region 126. Furthermore, the method of forming CMOS devices on an ETSOI substrate described above is fully compatible with conventional CMOS process technologies.

FIGS. 7 through 12 schematically illustrate method steps for fabrication of a CMOS semiconductor device structure on an ETSOI substrate using a gate first process in accordance with another embodiment of the present invention. In the gate first process, a true metal gate structure may be formed first and may be followed by normal CMOS process flow to fabricate the final device (as discussed in FIGS. 1-6). Some of the device features, structures, and process steps are similar, identical, or equivalent to counterparts described above with reference to FIGS. 1-6. For the sake of brevity, common features, structures, and process steps will not be redundantly described in detail here with reference to FIGS. 7-12.

FIG. 7 shows a structure similar to the device structure depicted in FIG. 1. However, this version of fabrication includes the formation of a true metal gate structure instead of a dummy gate. The true metal gate may include a high-k dielectric layer 702, metal layer 704, poly layer 706 and cap layer formed upon ETSOI layer 106. The high-k dielectric layer 702 may be formed on the ETSOI layer 106 by atomic layer deposition (ALD) or other suitable technique. The high-k dielectric layer 702 may include a thickness ranging from about 1 nm to about 10 nm. The high-k dielectric layer 702 may include materials listed above in conjunction with layer 204. The NFET device 124 may further include a metal gate layer 704 formed over high-k dielectric layer 702. The metal gate layer 704 may include a thickness ranging from about 10 to about 100 nm. The metal gate layer 706 may be formed by various deposition techniques such as chemical vapor deposition (CVD), physical vapor deposition (PVD or sputtering), plating, or other suitable technique. The metal gate layer 704 may include TiN, TaN, ZrSi₂, MoSi₂, TaSi₂, NiSi₂, WN, or other suitable material. The NFET device 124 may further include a polysilicon or poly layer 706 formed on the metal gate layer 704 by a deposition or other suitable process. This version of the fabrication process continues by forming a cap layer 708 overlying the poly layer 706. In various embodiments, the cap layer 708 includes an insulating material such as a nitride material. The cap layer 708 may be deposited over the poly layer 706 using, for example, CVD, LPCVD, or the like. The cap layer 708 may include a thickness ranging from about 5 to about 50 nm. In some embodiments, the gate structures formed in the NFET and PFET regions are substantially identical. Accordingly, the gate structure of the PFET device 126 will not be redundantly described here. However, in some embodiments, NFET and PFET gate structures may comprise different metals to achieve different gate workfunction.

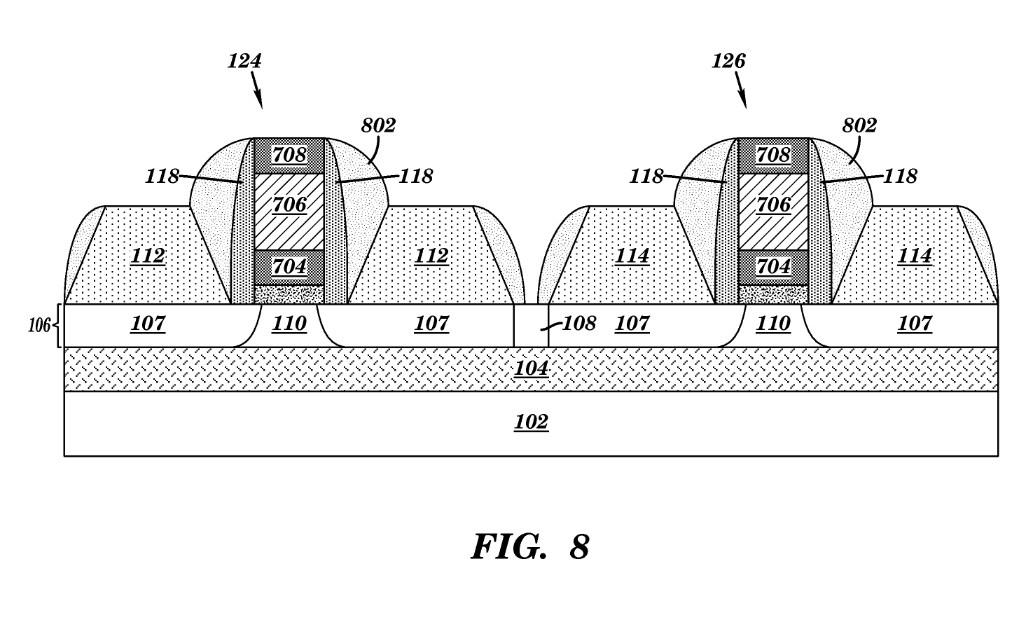

Turning to FIG. 8, the method of fabrication continues with the formation of second spacers 802 in the NFET 124 and PFET 126 regions. For the sake of clarity of description, spacers 118 will be referred to as “first spacers”. As illustrated in FIG. 8, second spacers 802 may be formed on the lateral edges of the gate structures, wherein the second spacers 802 cover the first spacers 118. The second spacers 802 may be substantially wider than the first spacers 118 and may be formed by depositing another insulating material such as a silicon nitride film (typically thicker than the film employed for the first spacers 118) and filling the space between the first spacers 118 and the corresponding RSD regions 112 and 114 as illustrated. In this embodiment, the second spacers 802 may be formed with a single insulating material film, however, multi-layer spacer films may also be employed and are contemplated as falling within the scope of various embodiments of the present invention.

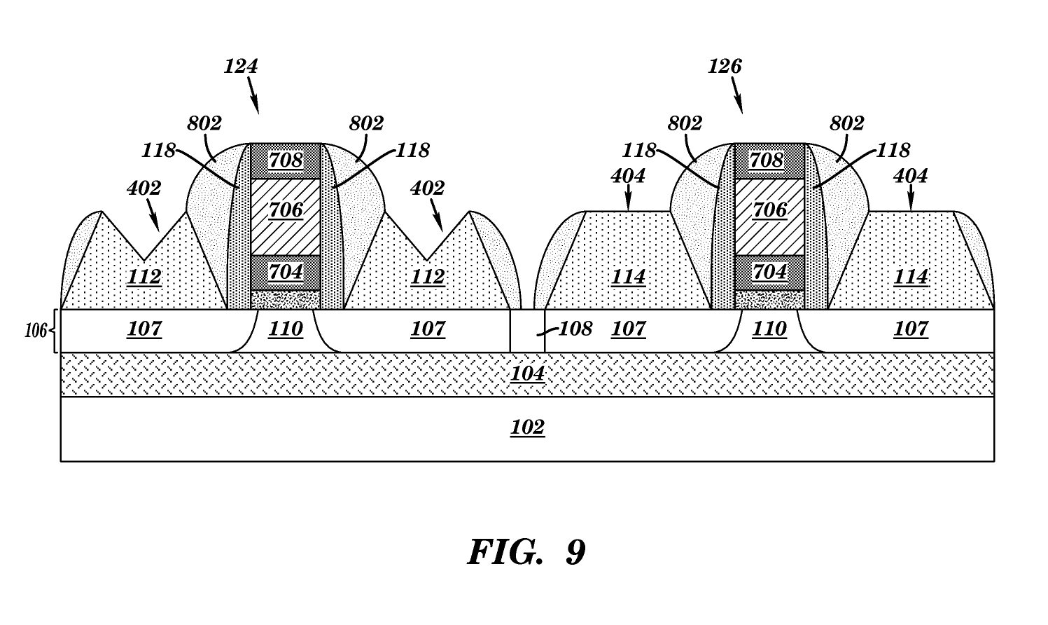

Referring now to FIG. 9, after the formation of the second spacers 802, the substantially V-shaped groove 402 on the top surface of the first pair of RSD regions 112 may be formed using an anisotropic wet etchant, as described above in conjunction with FIG. 4A. Again, advantageously, this etchant is highly selective, and thus leaves in place substantially horizontal top surface of each of the second pair of RSD regions 114 while the formation of the groove 402 on the top surface of each of the first pair of RSD regions 112 occurs. Therefore, as previously indicated, there is no need to form a mask layer over the PFET region 126.

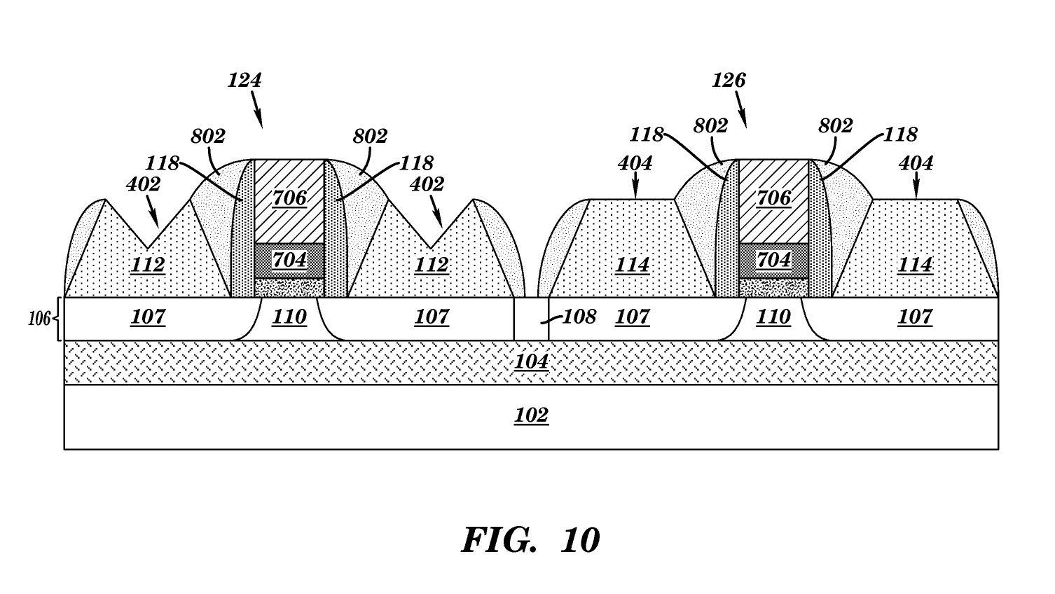

According to another aspect of this embodiment of the present invention, polysilicon 706 is used as a gate conductor and gate silicidation may be performed simultaneously with the silicidation of RSD regions 112 and 114. However, prior to the silicidation step, as shown in FIG. 10, the cap layer 708 is removed from the structure so that the underlying polysilicon gate conductor layer 706 is exposed. In accordance with this embodiment of the present invention, the cap layer 708 may be removed utilizing a dry etching process that selectively removes the nitride cap. For example, Reactive Ion Etching (RIE) can be used to selectively remove the cap layer 708.

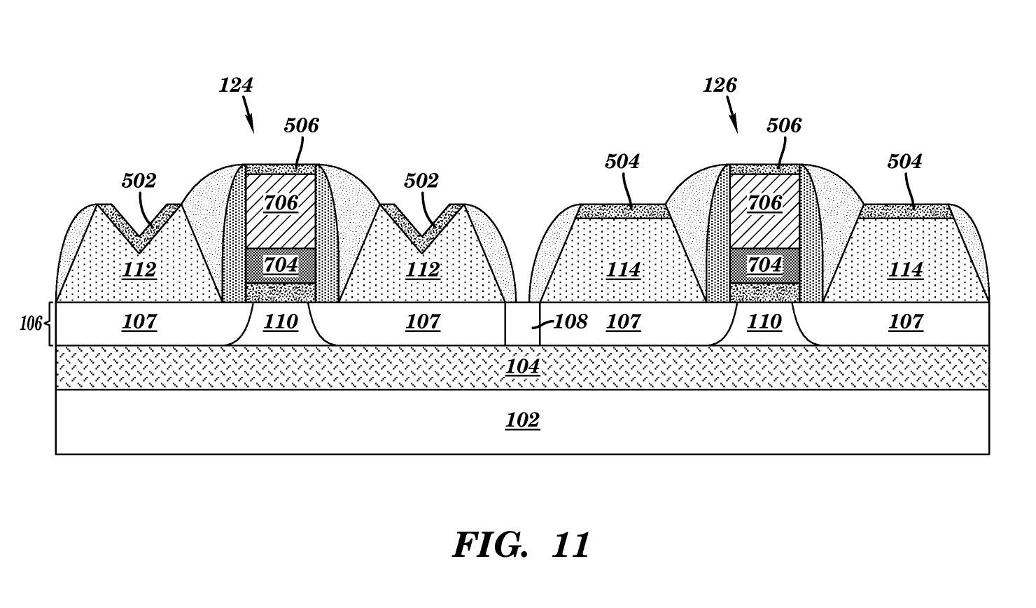

Referring now to FIG. 11, silicide layers 502, 504 and 506 may be formed above each pair of the RSD regions 112 and 114 and above polysilicon conductor layer 706, respectively, using traditional processing techniques described above in conjunction with FIG. 5. It should be noted, the silicide layers 502, 504 and 506 follow the topography of the underlying layers. In other words, in the NFET region 124, the silicide layer 502 has a substantially V-shaped profile, while in the PFET region 126, the silicide layer 504 has a substantially horizontal profile, as shown in 11. The silicide layer 506 overlying the polysilicon layer 706 may also have a substantially horizontal profile.

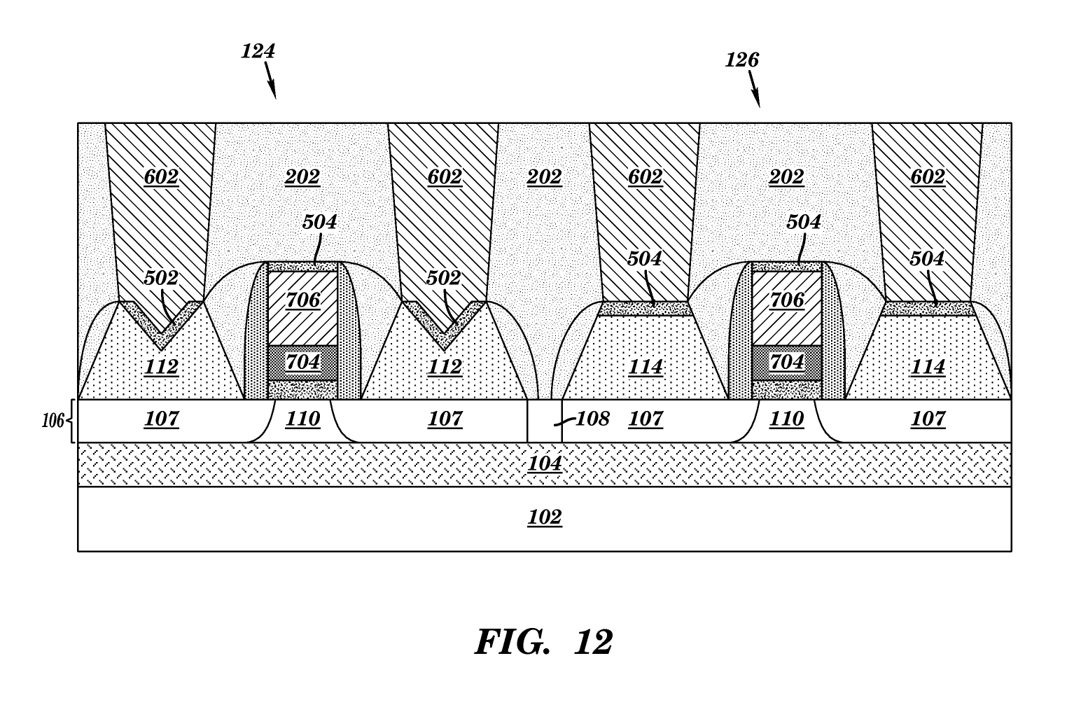

Once the silicidation step is performed, the process may continue with the conventional process flow for CMOSFET device formation. As shown in FIG. 12, the ILD layer 202 may be deposited and planarized, as discussed above in conjunction with FIG. 2. Next, contact trenches may be formed and filled with the contact metal 602 in the ILD layer 202, as discussed above in conjunction with FIG. 6. It should be noted that in this embodiment, similarly to the previous one, in the NFET region 124 contact metal 602 may be deposited over V-shaped silicide layer 502, while in the PFET region 126 contact metal 602 may be deposited over substantially horizontal silicide layer 504. Thus, FIG. 12 illustrates the final resultant structure after all of the gate-first process steps are performed in accordance with the present embodiment of the invention.

In another embodiment of the invention, as shown in FIG. 13, a “bulk” substrate may be used and CMOS devices, such as NFET device 124 and PFET device 126 may be formed on an upper surface of the “bulk” semiconductor substrate 1301. Preferably, the “bulk” substrate 1301 is a single crystal silicon wafer. In an embodiment of the present invention, the substrate 1301 may include a P-well region 1302 and an N-well region 1304 formed therein. The P-well and N-well regions 1302 and 1304, respectively, may be formed by implanting impurity ions into the bulk substrate 1301. As illustrated in FIG. 13, the P-well 1302 may be formed in the NFET region 124 and the N-well 1304 may be formed in the PFET region 126. The isolation region 108 may be formed in the bulk substrate 1301 between the P-well region 1302 and N-well region 1304, as illustrated in FIG. 13, by carrying out a conventional STI process. In bulk substrate embodiments of the present invention, prior to the formation of the source/drain regions, selective etching of the substrate 1301 may occur which may allow subsequent growth of embedded source/drain regions (“ESD” regions) 1312 and 1314. The first pair of ESD regions 1312 may comprise an epitaxially grown layer of, for example, silicon (or Si:C described above) formed in the etched away portion of the NFET region 124, while the second pair of ESD regions 1314 may comprise an epitaxially grown layer of silicon germanium (SiGe) formed in the etched away portion of the PFET region 126. The first and second pairs of ESD regions 1312 and 1314, respectively, may be doped with an appropriate dopant, as discussed above in conjunction with the RSD regions 112 and 114 of FIG. 1. The embedded source/drain regions 1312 and 1314 disposed in the bulk substrate 1301 of FIG. 13 are again spaced apart from the gate 206. In this embodiment, it will be appreciated that with a gate last process a dummy gate and an insulator other than a high k insulator 204 may be present when the source/drain regions are grown. The dummy gate is replaced with a metal gate 206 after the source/drain regions are grown for this process.

According to the present embodiment of the invention, the NFET device 124 and the PFET device 126 may also include the source/drain extensions 1308 formed adjacent the gate 206 and optionally aligned to the spacer 118. In general, the source/drain extensions 1308 may be formed to a shallow depth with a low concentration of impurities relative to a source/drain regions 1312 and 1314. Typically, the impurities used to form the source/drain extensions 1308 are of the same conductivity type as the impurities used to form the corresponding source/drain regions 1312 and 1314. It is to be understood that the source/drain extension 1308 can be formed via an angled or perpendicular implant, with respect to the top surface of the bulk substrate 1301, that can be aligned to the gate 206 or the spacer 118. A halo implant can help to decrease the length of the channel underneath the gate 206, which may be advantageous for minimizing punchthrough current and short channel effects, thereby helping to improve the performance of the NFET device 124 and the PFET device 126. In general, the halo regions 1306 can be formed by implanting impurities adjacent the gate 206 and/or spacer 118. At least in some embodiments, the halo regions 1306 can be formed by implanting the bulk substrate 1301 with impurities of opposite conductivity type to that of the impurities used to form the source/drain extensions 1308 and the source/drain regions 1312 and 1314. For example, in the NFET region 124 the halo regions 1308 can be formed with p-type impurities. The halo dopant material may be implanted at an angle so that the dopant material can be implanted underneath the gate 206 and the spacer 118. In general, the angle of the implantation is typically substantially less than ninety degrees relative to the top surface of the bulk substrate 1301, for example, between about 15 to about 75 degrees relative to the top surface of the bulk substrate 1301. However, in other embodiments, the halo dopant implant may be implanted perpendicular to the top surface of the bulk substrate 1301.

In this embodiment, once the ESD regions 1312 and 1314, halo regions 1306 and source/drain extension regions 1308 are obtained, the process continues with the gate last process flow for CMOSFET device formation on ETSOI substrate, described above in conjunction with FIGS. 2-6. It should be noted that in this embodiment, similarly to the previous ones, in the NFET region 124 contact metal 602 may be deposited over V-shaped silicide layer 502, while in the PFET region 126 contact metal 602 may be deposited over substantially horizontal silicide layer 504.

FIG. 14 illustrates alternative embodiment of a CMOS semiconductor device structure formed on a partially depleted (PD) SOI substrate using a gate last process. The device structure illustrated in FIG. 14 is almost the same as in the embodiment of FIG. 13. However, in the present embodiment, a PD SOI layer 1401 includes the BOX layer 104 overlying the silicon substrate layer 102 and a SOI layer 1402 overlying the BOX layer 104. In the present embodiment, SOI layer 1402 comprises silicon. It should be understood, that SOI layer 1402 may also be formed using other materials and/or alloys, such as silicon-germanium. The SOI layer 1402 has a thickness that ranges from about 30 nm to about 100 nm. Similar steps to those described above in connection with FIGS. 1-6 and 13 may be carried out to form NFET device 124 and PFET device 126 illustrated in FIG. 14. Thus, for the sake of brevity, common features, structures, and process steps will not be redundantly described in detail here with reference to FIG. 14.

FIG. 15 illustrates yet another embodiment of a CMOS semiconductor device structure formed on a bulk substrate using a gate first process. In the present embodiment, the bulk substrate 1301 may include the P-well region 1302, the N-well region 1304, the first and second pairs of ESD regions 1312 and 1314, respectively, the source/drain extensions 1308 and halo regions 1306, as described above in conjunction with FIG. 13. Once these regions are obtained, the process continues with the gate first process flow for CMOSFET device formation on ETSOI substrate, described above in conjunction with FIGS. 7-12.

FIG. 16 illustrates still another embodiment of a CMOS semiconductor device structure formed on a partially depleted (PD) SOI substrate using the gate first process. The structural elements of the NFET device 124 and PFET device 126 and the requisite process steps for forming these structures are described above in conjunction with FIGS. 7-12 and 14.

Other embodiments not specifically illustrated in Figures are also possible and enabled by this specification. For example, any substrate (bulk, SOI, PD SOI, ETSOI, etc.) can be used in combination with any one of the following source/drain configurations: raised source/drain (RSD), embedded source drain (ESD) or conventional source drains. Each of the combinations of substrate and source/drain type may be made by either a gate first or a gate last process previously described.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising”, when used in this specification, specify the presence of stated features, integers, steps, operations, elements, and/or components, but do not preclude the presence or addition of one or more other features, integers, steps, operations, elements, components, and/or groups thereof.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device structure comprising:
a substrate having a first region and a second region;
a first gate formed in the first region overlying a first channel region in the substrate; and
a first pair of source/drain regions formed in the first region on either side of the first channel region, each of the first pair of source/drain regions having a substantially V-shaped concave top surface.

2. The semiconductor device structure of claim 1, wherein the first region comprises an n-type field effect transistor (NFET) region and wherein each of the first pair of source/drain regions comprises a n-type doped region.

3. The semiconductor device structure of claim 2, wherein each of the first pair of source/drain regions comprises carbon doped silicon and wherein the n-type dopant comprises phosphorous or arsenic.

4. The semiconductor device structure of claim 2, wherein each of the first pair of source/drain regions has a silicide layer overlying the substantially V-shaped concave top surface.

5. The semiconductor device structure of claim 4, wherein the silicide layer has a substantially V-shaped profile.

6. The semiconductor device structure of claim 1, further comprising:
a second gate formed in the second region overlying a second channel region in the substrate; and
a second pair of source/drain regions formed in the second region on either side of the second channel region, each of the pair of source/drain regions having a substantially horizontal top surface.

7. The semiconductor device structure of claim 6, wherein the second region comprises a p-type field effect transistor (PFET) region and wherein each of the second pair of source/drain regions comprises a p-type doped region.

8. The semiconductor device structure of claim 7, wherein each of the second pair of source/drain regions comprises silicon germanium and wherein the p-type dopant comprises boron.

9. The semiconductor device structure of claim 6, wherein the first region is substantially adjacent to the second region.

10. The semiconductor device structure of claim 1, wherein the substrate comprises a partially depleted semiconductor-on-insulator (SOI) substrate and wherein the first pair of source/drain regions comprises embedded source/drain regions.

11. The semiconductor device structure of claim 1, wherein the substrate comprises a SOI substrate having a semiconductor layer with a thickness of less than 10 nanometers and wherein the first pair of source/drain regions comprises raised source/drain regions.

12. A method of forming a semiconductor device structure comprising:
providing a substrate having a first region and a second region;
forming a first gate in the first region, wherein the first gate overlies a first channel region in the substrate;
forming a first pair of source/drain regions in the first region on either side of the first channel region; and
forming a substantially V-shaped groove on a top surface of each of the first pair of source/drain regions.

13. The method of claim 12, wherein forming the substantially V-shaped groove comprises wet etching the top surface of each of the first pair of source/drain regions.

14. The method of claim 12, wherein forming the substantially V-shaped groove comprises wet etching the top surface of each of the first pair of source/drain regions using a tetramethyl ammonium hydroxide (TMAH) as an etchant.

15. The method of claim 12, wherein forming the substantially V-shaped groove comprises wet etching the top surface of each of the first pair of source/drain regions using ammonium hydroxide as an etchant.

16. The method of claim 12, further comprising:
forming a second gate in the second region, wherein the second gate overlies a second channel region in the substrate; and
forming a second pair of source/drain regions in the second region on either side of the second channel region.

17. The method of claim 12, wherein the first region comprises an n-type field effect transistor (NFET) region and wherein each of the first pair of source/drain regions comprises a n-type doped region

18. The method of claim 16, wherein forming the first pair of source/drain regions further comprises epitaxially growing carbon doped silicon and wherein the n-type dopant comprises phosphorous or arsenic.

19. The method of claim 15, wherein the second region comprises a p-type field effect transistor (PFET) region and wherein each of the second pair of source/drain regions comprises a p-type doped region.

20. The method of claim 18, wherein forming the second pair of source/drain regions further comprises epitaxially growing in-situ doped silicon germanium and wherein the p-type dopant comprises boron.

21. The method of claim 13, wherein the wet etching comprises a self-limiting etching process.

22. The method of claim 12, further comprising forming a silicide layer over the substantially V-shaped groove on the top surface of each of the first pair of source/drain regions.

23. The method of claim 15, further comprising forming a silicide layer over a substantially horizontal top surface of each of the second pair of source/drain regions.

24. The method of claim 12, wherein providing the substrate comprises providing a partially depleted SOI substrate and wherein forming the first pair of source/drain regions comprises forming embedded source/drain regions.

25. The method of claim 12, wherein providing the substrate comprises providing a SOI substrate having a semiconductor layer with a thickness of less than 10 nanometers and wherein forming the first pair of source/drain regions comprises forming raised source/drain regions.
